(19) United States
(12) Patent Application Publication
(10) Pub. No.: US 2024/0324433 A1
(43) Pub. Date: Sep. 26, 2024

(54) METHOD AND APPARATUS FOR MANUFACTURING DISPLAY DEVICE

(71) Applicant: Samsung Display Co., LTD., Yongin-si (KR)

(72) Inventors: Jeongkuk KIM, Yongin-si (KR); Arong KIM, Yongin-si (KR); Youngmin MOON, Yongin-si (KR); Youngho PARK, Yongin-si (KR); Heemin PARK, Yongin-si (KR); Sungsoon IM, Yongin-si (KR); Wonje CHO, Yongin-si (KR); Junho JO, Yongin-si (KR)

(21) Appl. No.: 18/380,440

(22) Filed: Oct. 16, 2023

(30) Foreign Application Priority Data
Mar. 24, 2023 (KR) 10-2023-0039058
May 24, 2023 (KR) 10-2023-0067142

(51) Int. Cl. H10K 71/16; C23C 14/04; H10K 71/20

(52) U.S. Cl. CPC H10K 71/166; C23C 14/042; H10K 71/233

(57) ABSTRACT

An apparatus for manufacturing a display device includes a chamber, a mask assembly disposed in the chamber and facing a display substrate, a magnetic force portion which is disposed in the chamber and applies magnetic force to the mask assembly, and a deposition source which is disposed in the chamber, faces the mask assembly and supplies a deposition material so that the deposition material passes through the mask assembly and is deposited on the display substrate, where the mask assembly includes a first mask layer in which a first mask opening is defined, and a second mask layer which is disposed on the first mask layer and in which a second mask opening overlapping the first mask opening is defined, where the second mask layer includes a 2-1^{st} mask portion, and a 2-2^{nd} mask portion protruding from the 2-1^{st} mask portion toward the display substrate.

This application claims priority to Korean Patent Application No. 10-2023-0039058, filed on Mar. 24, 2023, and Korean Patent Application No. 10-2023-0067142, filed on May 24, 2023, and all the benefits accruing therefrom under 35 U.S.C. § 119, the content of which in their entirety is herein incorporated by reference.

### BACKGROUND

### 1. Field

Embodiments relate to a method and an apparatus, and more particularly, to a method and apparatus for manufacturing a display device.

### 2. Description of the Related Art

Display devices visually display data. Display devices may provide images by light-emitting diodes. Uses of display devices are diversifying. Accordingly, various designs for improving the quality of display devices are being attempted.

### SUMMARY

Embodiments include a mask assembly in which a contact area with a display substrate is reduced.

Embodiments include a method of manufacturing a mask assembly in which a manufacturing process is simple.

However, this technical problem is an example, and technical problems to be solved by the disclosure is not limited thereto.

Additional features will be set forth in part in the description which follows and, in part, will be apparent from the description, or may be learned by practice of the presented embodiments of the disclosure.

In an embodiment of the disclosure, an apparatus for manufacturing a display device includes a chamber, a mask assembly disposed in the chamber to face a display substrate, a magnetic force portion which is disposed in the chamber and applies magnetic force to the mask assembly, and a deposition source which is disposed in the chamber, faces the mask assembly and supplies a deposition material such that the deposition material passes through the mask assembly and is deposited on the display substrate, where the mask assembly includes a first mask layer in which a first mask opening is defined, and a second mask layer which is disposed on the first mask layer and in which a second mask opening overlapping the first mask opening is defined, where the second mask layer includes a 2-1^{st} mask portion, and a 2-2^{nd} mask portion protruding from the 2-1^{st} mask portion toward the display substrate.

In an embodiment, an upper surface of the 2-2^{nd} mask portion may contact the display substrate.

In an embodiment, the display substrate may be exposed from the second mask layer through the second mask opening.

In an embodiment, an upper surface of the 2-1^{st} mask portion may be spaced apart from the display substrate.

In an embodiment, a width of the second mask opening may gradually decrease in a direction toward the display substrate.

In an embodiment, the second mask opening may include a 2-1^{st} mask opening defined in the 2-1^{st} mask portion, and a 2-2^{nd} mask opening extending to the 2-1^{st} mask opening and defined in the 2-2^{nd} mask portion.

In an embodiment, the 2-1^{st} mask portion and the 2-2^{nd} mask portion may be unitary with each other as a single body.

In an embodiment of the disclosure, a method of manufacturing a display device includes arranging a display substrate in a chamber, arranging a mask assembly in the chamber, applying, by a magnetic force portion, magnetic force to the mask assembly, and supplying, by a deposition source, a deposition material toward the mask assembly, where the arranging the mask assembly includes arranging a first photoresist layer on a first mask layer, arranging a second mask layer over the first photoresist layer, etching the second mask layer, etching the first mask layer, and removing the first photoresist layer.

In an embodiment, the arranging the first photoresist layer on the first mask layer may include arranging a first photoresist material on the first mask layer, arranging a first photomask over the first photoresist material, where a first photomask opening, exposing the first photoresist material through the first photomask opening, and developing the first photoresist material into the first photoresist layer may be defined in the first photomask.

In an embodiment, the arranging the first photoresist layer may further include baking the first photoresist material.

In an embodiment, a side surface of the first photoresist layer may be inclined with respect to an upper surface of the first mask layer.

In an embodiment, a second mask opening may be defined in the second mask layer by the removing the first photoresist layer.

In an embodiment, the display substrate may be exposed from the second mask layer through the second mask opening.

In an embodiment, a width of the second mask opening may gradually decrease in a direction toward the display substrate.

In an embodiment, the second mask layer may include a 2-1^{st} mask portion, and a 2-2^{nd} mask portion protruding from the 2-1^{st} mask portion toward the display substrate.

In an embodiment, an upper surface of the 2-2^{nd} mask portion may contact the display substrate.

In an embodiment, an upper surface of the 2-1^{st} mask portion may be spaced apart from the display substrate.

In an embodiment, the 2-1^{st} mask portion and the 2-2^{nd} mask portion may be unitary with each other as a single body.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic cross-sectional view of an embodiment of an apparatus for manufacturing a display device,

FIG. 2 is a schematic cross-sectional view of an embodiment of a mask assembly, and FIG. 3 is a schematic plan view of an embodiment of a portion of a second mask layer;

FIGS. 4 to 15 are cross-sectional views of a mask assembly, for describing an embodiment of a method of manufacturing a display device;

FIG. 16 is a schematic perspective view of an embodiment of a display device;

FIG. 17 is a schematic cross-sectional view of an embodiment of a display device;

FIG. 18 is a schematic plan view of an embodiment of a display panel;

FIG. 19 is an equivalent circuit diagram of an embodiment of a pixel included in a display device; and

FIG. 20 is a schematic cross-sectional view taken along line D-D′ of an embodiment of a display device of FIG. 18.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the description allows for various changes and numerous embodiments, illustrative embodiments will be illustrated in the drawings and described in the written description. Effects and features of embodiments and methods of accomplishing the same will become apparent from the following detailed description of the embodiments, taken in conjunction with the accompanying drawings. However, the illustrated embodiments may have different forms and should not be construed as being limited to the descriptions set forth herein.

Embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a certain process order may be performed differently from the described order. For example, two consecutively described processes may be performed substantially at the same time or performed in an order opposite to the described order.

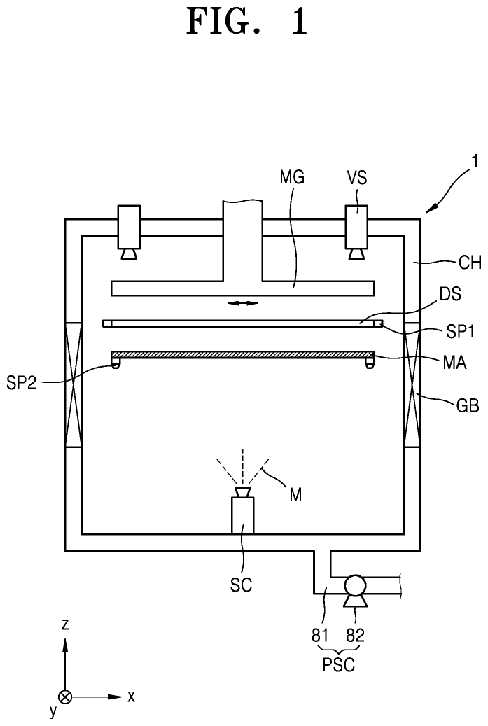

FIG. 1 is a schematic cross-sectional view of an embodiment of an apparatus 1 for manufacturing a display device.

The apparatus 1 may include a chamber CH, a first support SP1, a second support SP2, a mask assembly MA, a deposition source SC, a magneticforce portion MG, a vision portion VS, and a pressure controller PSC.

The chamber CH may define a space therein and may receive a display substrate DS and the mask assembly MA. In this regard, a portion of the chamber CH may be opened, and a gate valve GB may be provided in the opened portion of the chamber CH. In this case, the opened portion of the chamber CH may be open or closed according to an operation of the gate valve GB.

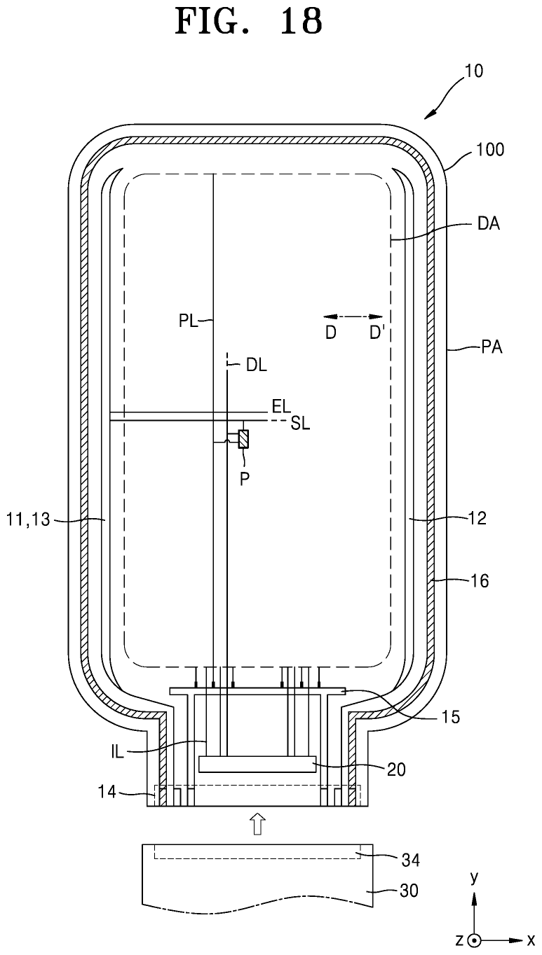

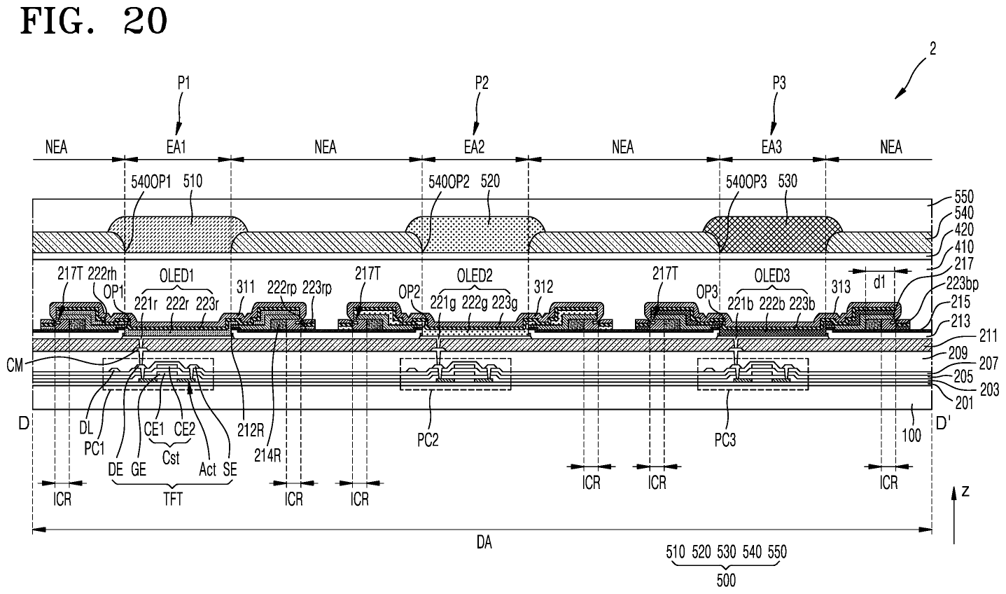

In this regard, the display substrate DS may refer to the display substrate DS in the process of manufacturing a display device, in which at least one of an organic layer, an inorganic layer, and a metal layer is deposited on a substrate 100 (refer to FIGS. 18 and 20) described below. In an alternative embodiment, the display substrate DS may be the substrate 100 on which none of an organic layer, an inorganic layer, and a metal layer has been deposited yet.

The first support SP1 may support the display substrate DS. In this regard, the first support SP1 may be in the form of a plate fixed inside the chamber CH. In another embodiment, the first support SP1 may be in the form of a shuttle on which the display substrate DS is seated and which is linearly moveable inside the chamber CH. In another embodiment, the first support SP1 may include an electrostatic chuck or an adhesive chuck disposed in the chamber CH to be fixed to the chamber CH or movable inside the chamber CH.

The second support SP2 may support the mask assembly MA. In this regard, the second support SP2 may be disposed inside the chamber CH. The second support SP2 may fine-adjust a position of the mask assembly MA. In this regard, the second support SP2 may include a separate driver or alignment unit for moving the mask assembly MA in different directions.

In another embodiment, the second support SP2 may be in the form of a shuttle. In this case, the second support SP2 may have the mask assembly MA seated thereon and may transport the mask assembly MA. In an embodiment, the second support SP2 may move out of the chamber CH to have the mask assembly MA seated thereon and then may enter the chamber CH from outside the chamber CH, for example.

In the above case, the first support SP1 and the second support SP2 may be unitary with each other. In this case, the first support SP1 and the second support SP2 may include a movable shuttle. In this regard, the first support SP1 and the second support SP2 may include a structure in which the mask assembly MA and the display substrate DS are fixed to each other with the display substrate DS seated on the mask assembly MA, and may linearly move the display substrate DS and the mask assembly MA simultaneously.

However, hereinafter, a form in which the first support SP1 and the second support SP2 are separated from each other and arranged at different positions and a form in which the first support SP1 and the second support SP2 are arranged inside the chamber CH will be mainly described in detail for convenience.

The mask assembly MA may be disposed in the chamber CH to face the display substrate DS. A deposition material M may pass through the mask assembly MA and be deposited on the display substrate DS.

The deposition source SC may face the mask assembly MA, and may supply the deposition material M such that the deposition material M passes through the mask assembly MA and is deposited on the display substrate DS. In this regard, the deposition source SC may evaporate or sublimate the deposition material M by applying heat to the deposition material M. The deposition source SC may be fixed inside the chamber CH or may be disposed inside the chamber CH to be linearly moveable in one direction.

The magnetic force portion MG may be disposed inside the chamber CH to face the display substrate DS and/or the mask assembly MA. In this regard, the magnetic force portion MG may apply magnetic force to the mask assembly MA, thereby pressing the mask assembly MA toward the display substrate DS.

The vision portion VS may be disposed in the chamber CH and may capture images of positions of the display substrate DS and the mask assembly MA. In this regard, the vision portion VS may include a camera for capturing images of the display substrate DS and the mask assembly MA. Based on the images captured by the vision portion VS, positions of the display substrate DS and the mask assembly MA may be identified, and the mask assembly MA may be checked for deformation. In addition, based on the images, a position of the display substrate DS may be fine-adjusted by the first support SP1, or a position of the mask assembly MA may be fine-adjusted by the second support SP2. However, hereinafter, a case where a position of the mask assembly MA is fine-adjusted by the second support SP2 to align positions of the display substrate DS and the mask assembly MA with each other will be mainly described in detail.

The pressure controller PSC may be connected to the chamber CH to control the internal pressure of the chamber CH. In an embodiment, the pressure controller PSC may adjust the internal pressure of the chamber CH to a level that is the same as or similar to that of atmospheric pressure, for example. In addition, the pressure controller PSC may adjust the internal pressure of the chamber CH to a level that is the same as or similar to that of a vacuum state.

The pressure controller PSC may include a connection pipe 81 connected to the chamber CH and a pump 82 provided on the connection pipe 81. In this regard, external air may be introduced through the connection pipe 81 or gas inside the chamber CH may be guided to the outside through the connection pipe 81 according to an operation of the pump 82.

According to a method of manufacturing a display device (not shown) by the apparatus 1 described above, the display substrate DS may be prepared first.

The pressure controller PSC may maintain the internal pressure of the chamber CH at a level that is the same as or similar to that of atmospheric pressure, and the gate valve GB may operate to open the opened portion of the chamber CH.

After that, the display substrate DS may be inserted into the chamber CH from outside the chamber CH. In this regard, the display substrate DS may be inserted into the chamber CH in various ways. In an embodiment, the display substrate DS may be inserted into the chamber CH from outside the chamber CH through a robot arm, etc., disposed outside the chamber CH, for example. In another embodiment, when the first support SP1 is in the form of a shuttle, the first support SP1 may be carried out of the chamber CH from inside the chamber CH, and then, the display substrate DS may be seated on the first support SP1 through a separate robot arm, etc., disposed outside the chamber CH, and the first support SP1 may be inserted into the chamber CH from outside the chamber CH.

As described above, the mask assembly MA may be disposed inside the chamber CH. In another embodiment, in the same or similar manner as the display substrate DS, the mask assembly MA may be inserted into the chamber CH from outside the chamber CH.

When the display substrate DS is inserted into the chamber CH, the display substrate DS may be seated on the first support SP1. In this regard, the vision portion VS may capture images of positions of the display substrate DS and the mask assembly MA. Positions of the display substrate DS and the mask assembly MA may be identified based on the images captured by the vision portion VS. In this regard, the apparatus 1 may include a separate controller (not shown) to identify positions of the display substrate DS and the mask assembly MA.

When positions of the display substrate DS and the mask assembly MA have been identified, the second support SP2 may fine-adjust the position of the mask assembly MA.

After that, the deposition source SC may operate to supply the deposition material M toward the mask assembly MA, and the deposition material M having passed through the mask assembly MA may be deposited on the display substrate DS. In this regard, the deposition source SC may move parallel to the display substrate DS and the mask assembly MA, or the display substrate DS and the mask assembly MA may move parallel to the deposition source SC. That is, the deposition source SC may move relative to the display substrate DS and the mask assembly MA. In this regard, the pump 82 may suck in gas inside the chamber CH and discharge the gas to the outside, thereby maintaining the internal pressure of the chamber CH at a level that is the same as or similar to that of a vacuum state.

As described above, the deposition material M supplied from the deposition source SC may pass through the mask assembly MA and be deposited on the display substrate DS, and accordingly, a plurality of layers which are stacked on a display device described below, e.g., at least one of an organic layer, an inorganic layer, and a metal layer, may be formed.

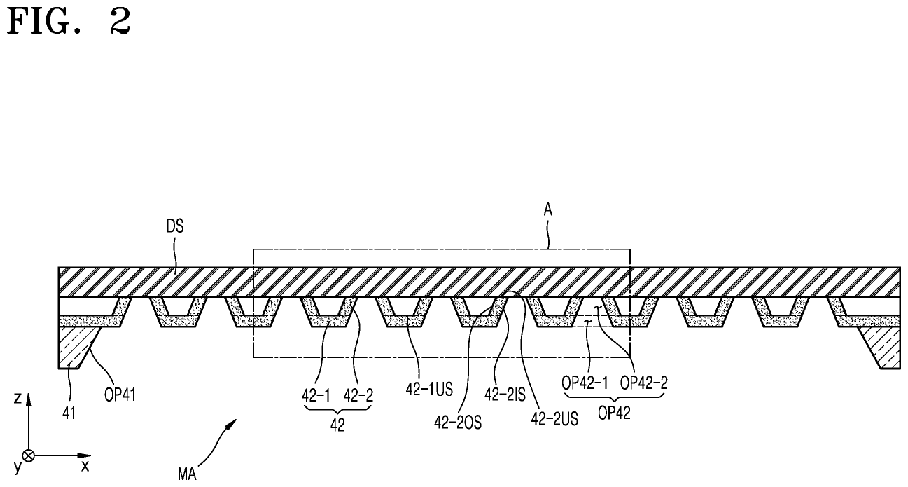

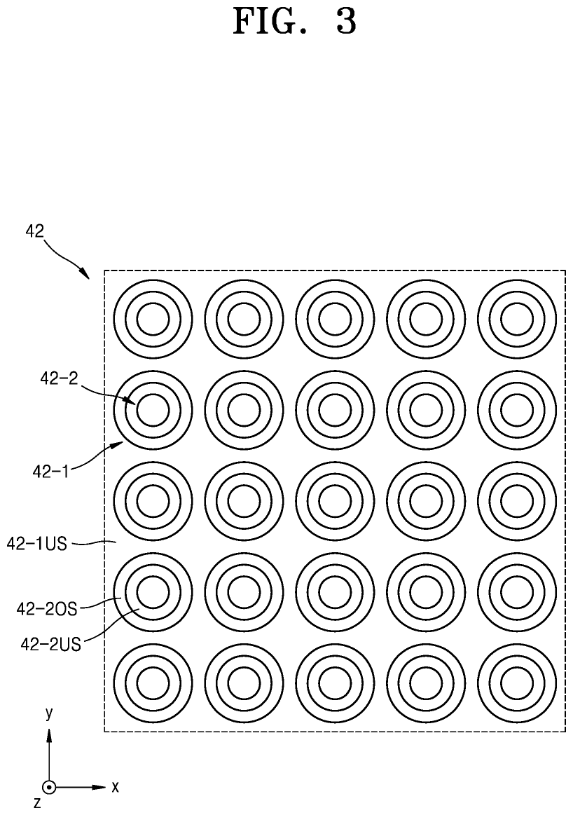

FIG. 2 is a schematic cross-sectional view of an embodiment of the mask assembly MA in an embodiment, and FIG. 3 is a schematic plan view of an embodiment of a portion of a second mask layer 42. More specifically, FIG. 3 is a diagram of a region A of FIG. 2 viewed from the top.

Referring to FIGS. 2 and 3, the mask assembly MA may include a first mask layer 41 and the second mask layer 42.

A first mask opening OP41 may be defined in the first mask layer 41 to allow the deposition material M (refer to FIG. 1) to pass therethrough. An inner circumferential surface may be formed in the first mask layer 41 by the first mask opening OP41. The first mask opening OP41 may be defined in a central portion of the first mask layer 41. A central portion of the second mask layer 42 may be exposed through the first mask opening OP41 in the first mask layer 41. Although FIG. 2 shows the inner circumferential surface of the first mask layer 41 inclined with respect to the second mask layer 42 in a cross-sectional view, this is merely one of embodiments, and the inner circumferential surface of the first mask layer 41 may be perpendicular to the second mask layer 42.

The first mask layer 41 may include a silicon material. In an embodiment, the first mask layer 41 may include at least one of silicon oxide (SiOx), silicon nitride (SiNx), and silicon oxynitride (SiOxNy), for example.

The second mask layer 42 may be disposed on the first mask layer 41. The second mask layer 42 may be supported by the first mask layer 41. The second mask layer 42 may include at least one of silicon oxide (SiOx), silicon nitride (SiNx), and silicon oxynitride (SiOxNy).

A second mask opening OP42 may be defined in the second mask layer 42. The second mask opening OP42 may overlap the first mask opening OP41. The second mask opening OP42 may include a plurality of second mask openings OP42. In an embodiment, as shown in FIG. 3, the plurality of second mask openings OP42 may be defined in a first direction (e.g., a y-axis direction) and a second direction (e.g., an x-axis direction), for example. The second mask layer 42 may include a 2-1^{st} mask portion 42-1 and a 2-2^{nd} mask portion 42-2.

The 2-1^{st} mask portion 42-1 may be disposed on the first mask layer 41, and the 2-2^{nd} mask portion 42-2 may be disposed on the 2-1^{st} mask portion 42-1. The 2-2^{nd} mask portion 42-2 may protrude from the 2-1^{st} mask portion 42-1 toward the display substrate DS. The 2-1^{st} mask portion 42-1 and the 2-2^{nd} mask portion 42-2 may be unitary with each other as a single body. An upper surface 42-2US of the 2-2^{nd} mask portion 42-2 may contact the display substrate DS, and an upper surface 42-1 US of the 2-1^{st} mask portion 42-1 may be spaced apart from the display substrate DS.

Because the 2-2^{nd} mask portion 42-2 protrudes from the 2-1^{st} mask portion 42-1, a contact area between the mask assembly MA and the display substrate DS may be reduced. Damage to the display substrate DS due to contact between the display substrate DS and the mask assembly MA may be reduced. Accordingly, quality of the display substrate DS and durability of the mask assembly MA may be improved.

The display substrate DS may be exposed from the second mask layer 42 through the second mask opening OP42. The second mask opening OP42 may include a 2-1^{st} mask opening OP42-1 and a 2-2^{nd} mask opening OP42-2. The 2-1^{st} mask opening OP42-1 may be defined in the 2-1^{st} mask portion 42-1, and the 2-2^{nd} mask opening OP42-2 may be defined in the 2-2^{nd} mask portion 42-2. The 2-1^{st} mask opening OP42-1 and the 2-2^{nd} mask opening OP42-2 may be connected to each other. Accordingly, the deposition material M (refer to FIG. 1) may sequentially pass through the 2-1^{st} mask opening OP42-1 and the 2-2^{nd} mask opening OP42-2 and be deposited on the display substrate DS.

A width of the second mask opening OP42 may gradually decrease in a third direction (e.g., a +z-axis direction) toward the display substrate DS. In a cross-sectional view, the second mask opening OP42 may be inversely tapered with respect to the upper surface 42-1US of the 2-1^{st} mask portion 42-1. That is, an inner circumferential surface 42-2IS of the 2-2^{nd} mask portion 42-2 defining the 2-2^{nd} mask opening OP42-2 may be inclined with respect to the upper surface 42-1 US of the 2-1^{st} mask portion 42-1. An outer circumferential surface 42-2OS of the 2-2^{nd} mask portion 42-2 may also be inclined with respect to the upper surface 42-1 US of the 2-1^{st} mask portion 42-1.

Because a width of the second mask opening OP42 gradually decreases in the third direction (e.g., the +z-axis direction), a shadow phenomenon in which the deposition material M (refer to FIG. 1) is caught in the mask assembly MA and fails to reach the display substrate DS may be reduced. Accordingly, quality of the display substrate DS may be improved.

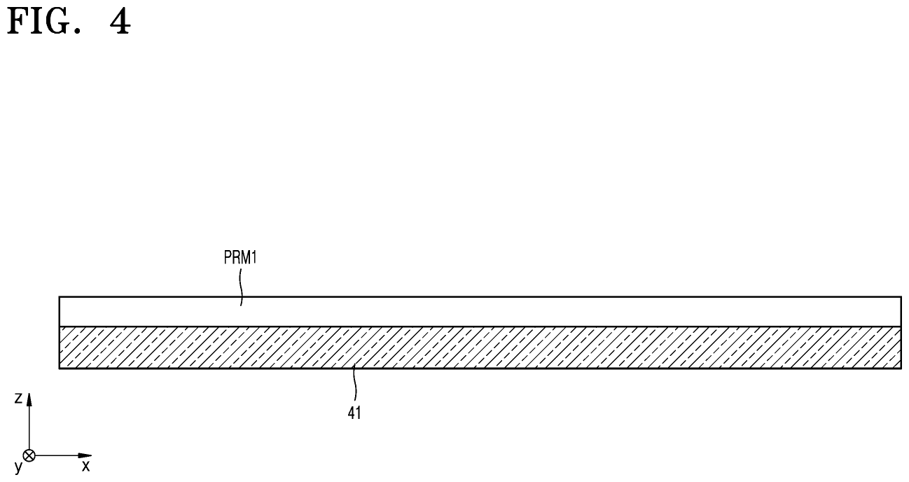

FIGS. 4 to 15 are cross-sectional views of an embodiment of the mask assembly MA, for describing a method of manufacturing a display device.

In FIGS. 4 to 15, the same reference numerals as those in FIGS. 1 to 3 denote the same elements, and thus, a repeated description thereof is omitted below.

Referring to FIGS. 4 to 15, the method of manufacturing a display device may include an operation of arranging the mask assembly MA inside the chamber CH (refer to FIG. 1).

The operation of arranging the mask assembly MA may include an operation of arranging a first photoresist layer PRL1 on the first mask layer 41, an operation of arranging the second mask layer 42 over the first photoresist layer PRL1, an operation of etching the second mask layer 42, an operation of etching the first mask layer 41, and an operation of removing the first photoresist layer PRL1.

Referring to FIGS. 4 to 7, the operation of arranging the first photoresist layer PRL1 on the first mask layer 41 may be seen.

First, referring to FIG. 4, the operation of arranging the first photoresist layer PRL1 on the first mask layer 41 may include an operation of arranging a first photoresist material PRM1 on the first mask layer 41. The first photoresist material PRM1 may be a photosensitive material.

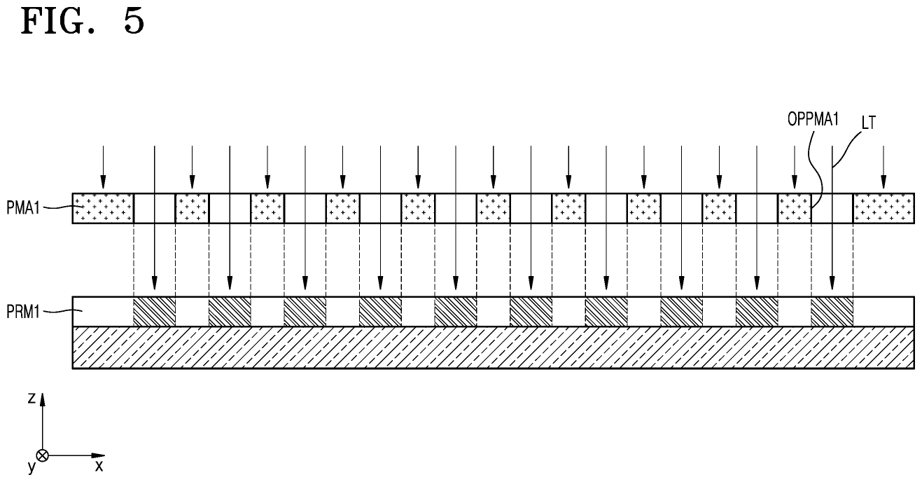

Referring to FIG. 5, the operation of arranging the first photoresist layer PRL1 on the first mask layer 41 may include an operation of arranging a first photomask PMA1 over the first photoresist material PRM1, the first photomask PMA1 in which a first photomask opening OPPMA1 is defined, and an operation of exposing the first photoresist material PRM1 through the first photomask opening OPPMA1.

Light LT may pass through the first photomask opening OPPMA1 and contact the first photoresist material PRM1. In an embodiment, the light LT may be ultraviolet light. During this process, solubility of a portion of the first photoresist material PRM1 that overlaps the first photomask opening OPPMA1 may decrease, for example. In addition, solubility of a portion of the first photoresist material PRM1 that does not overlap the first photomask opening OPPMA1 may increase.

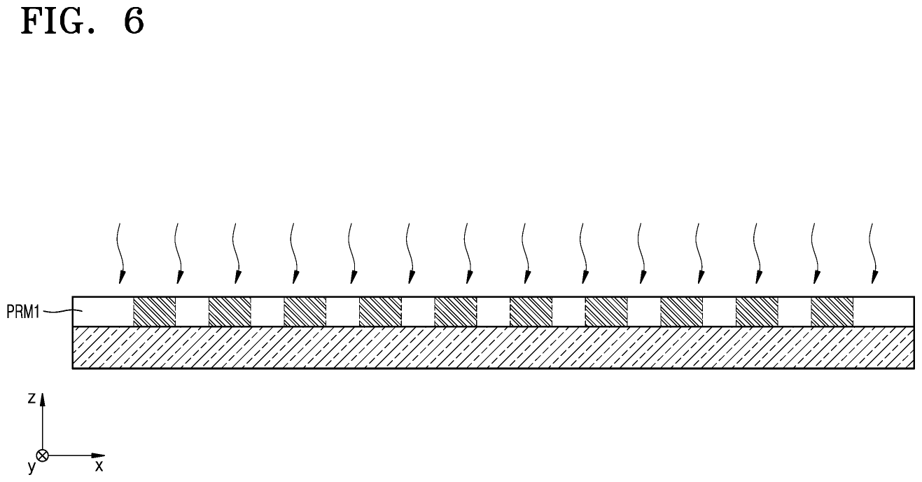

Referring to FIG. 6, the operation of arranging the first photoresist layer PRL1 on the first mask layer 41 may include an operation of baking the first photoresist material PRM1. A process of baking the first photoresist material PRM1 may be a process of hard baking the first photoresist material PRM1. A temperature at which the first photoresist material PRM1 is baked may be about 0 degrees Celsius or greater and about 125 degrees Celsius or less.

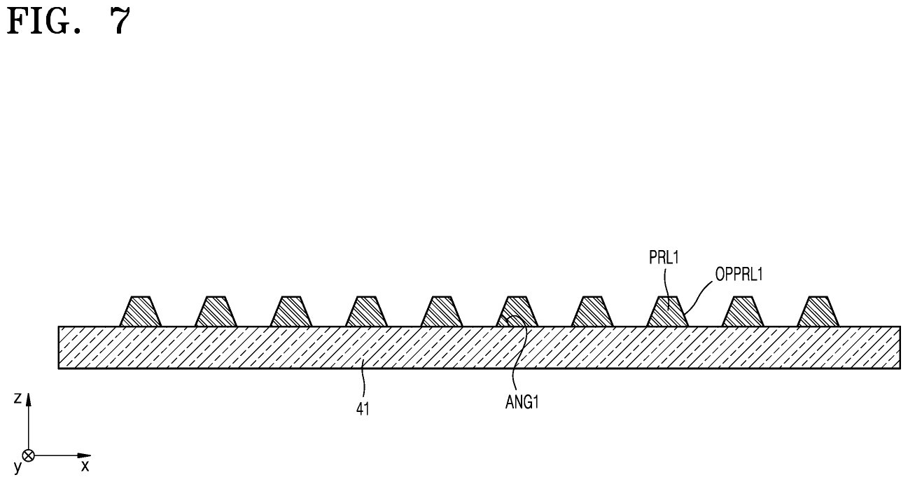

Referring to FIG. 7, the operation of arranging the first photoresist layer PRL1 on the first mask layer 41 may include an operation of developing the first photoresist material PRM1 (refer to FIG. 6) into the first photoresist layer PRL1. The operation of developing the first photoresist material PRM1 (refer to FIG. 6) may be an operation of removing a portion of the first photoresist material PRM1 (refer to FIG. 6) by an alkaline developer. In this regard, a portion of the first photoresist material PRM1 (refer to FIG. 6) that has not been brought into contact with ultraviolet light in FIG. 5 may be removed.

The first photoresist layer PRL1 may be supported by the first mask layer 41. A side surface of the first photoresist layer PRL1 may be inclined with respect to an upper surface of the first mask layer 41 by a first angle ANG1. In this regard, the first angle ANG1 may be determined according to the temperature described in FIG. 6 at which the first photoresist material PRM1 is baked. As the temperature at which the first photoresist material PRM1 is baked increases, the first angle ANG1 may decrease. Accordingly, the first angle ANG1 may be easily adjusted by controlling the baking temperature.

It has been described in FIGS. 4 to 7 that a negative photoresist material having solubility decreased in contact with the light LT is used. However, this is merely one of embodiments, and a positive photoresist material having solubility increased in contact with the light LT may be used.

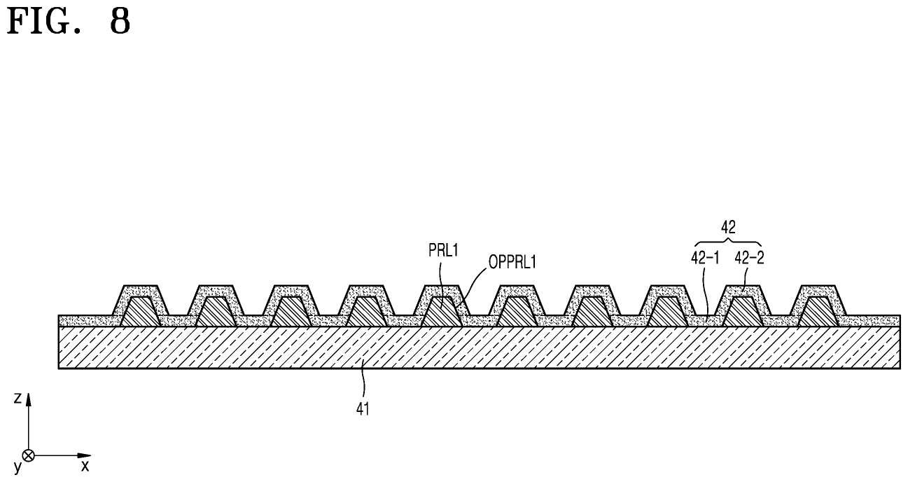

Referring to FIG. 8, the operation of arranging the second mask layer 42 over the first photoresist layer PRL1 may be seen.

The second mask layer 42 may cover the first photoresist layer PRL1. Because at least a portion of the second mask layer 42 is disposed in a first photo opening OPPRL1, the second mask layer 42 and the first mask layer 41 may contact each other. The second mask layer 42 may be divided into the 2-1^{st} mask portion 42-1 and the 2-2^{nd} mask portion 42-2.

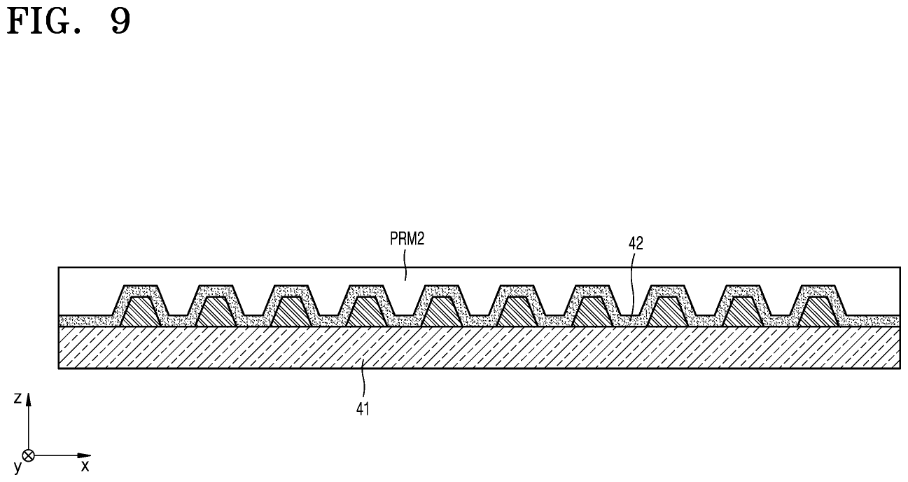

Referring to FIGS. 9 to 13, the operation of etching the second mask layer 42 may be seen. The second mask layer 42 may be etched through a photolithography process. The operation of etching the second mask layer 42 may include an operation of arranging a second photoresist layer PRL2 on the second mask layer 42, an operation of etching a portion of the second mask layer 42 that overlaps a second photo opening OPPRL2, and an operation of removing the second photoresist layer PRL2.

Referring to FIG. 9, the operation of arranging the second photoresist layer PRL2 on the second mask layer 42 may include an operation of arranging a second photoresist material PRM2 on the second mask layer 42. The second photoresist material PRM2 may be a photosensitive material.

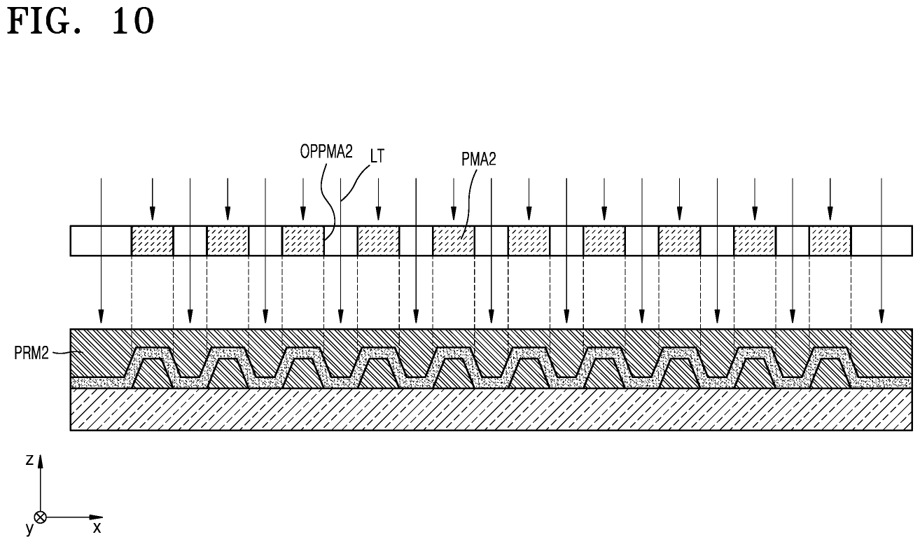

Referring to FIG. 10, the operation of arranging the second photoresist layer PRL2 on the second mask layer 42 may include an operation of arranging a second photomask PMA2 over the second photoresist material PRM2, the second photomask PMA2 in which a second photomask opening OPPMA2 is defined, and an operation of exposing the second photoresist material PRM2 through the second photomask opening OPPMA2.

The second photomask opening OPPMA2 may overlap the 2-1^{st} mask portion 42-1. The second photomask PMA2 may overlap the 2-2^{nd} mask portion 42-2. That is, the second photomask PMA2 may overlap the first photoresist layer PRL1.

Light LT may pass through the second photomask opening OPPMA2 and contact the second photoresist material PRM2. In an embodiment, the light LT may be ultraviolet light. During this process, solubility of a portion of the second photoresist material PRM2 that overlaps the second photomask opening OPPMA2 may decrease, for example. In addition, solubility of a portion of the second photoresist material PRM2 that does not overlap the second photomask opening OPPMA2 may increase.

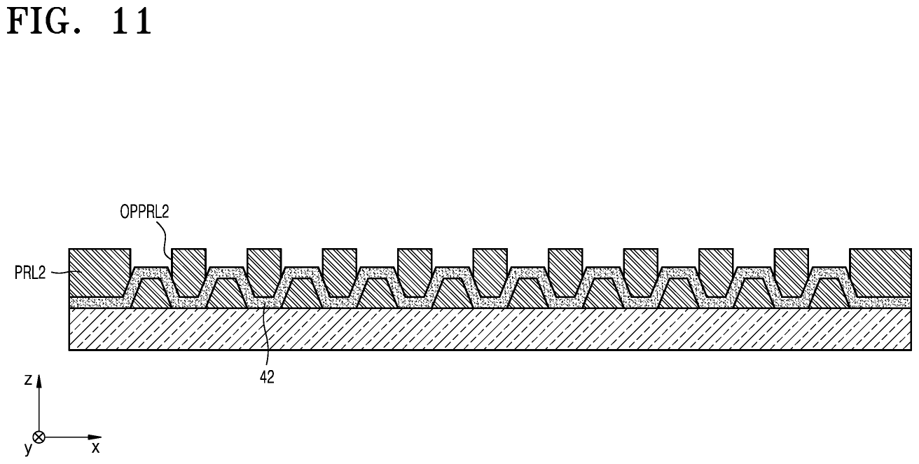

Referring to FIG. 11, the operation of arranging the second photoresist layer PRL2 on the second mask layer 42 may include an operation of developing the second photoresist material PRM2 (refer to FIG. 10) into the second photoresist layer PRL2. The operation of developing the second photoresist material PRM2 (refer to FIG. 10) may be an operation of removing a portion of the second photoresist material PRM2 (refer to FIG. 10) by an alkaline developer. In this regard, a portion of the second photoresist material PRM2 (refer to FIG. 10) that has not been brought into contact with ultraviolet light in FIG. 10 may be removed. The second photoresist layer PRL2 may be supported by the second mask layer 42.

It has been described in FIGS. 9 to 11 that a negative photoresist material having solubility decreased in contact with the light LT is used. However, this is merely one of embodiments, and a positive photoresist material having solubility increased in contact with the light LT may be used.

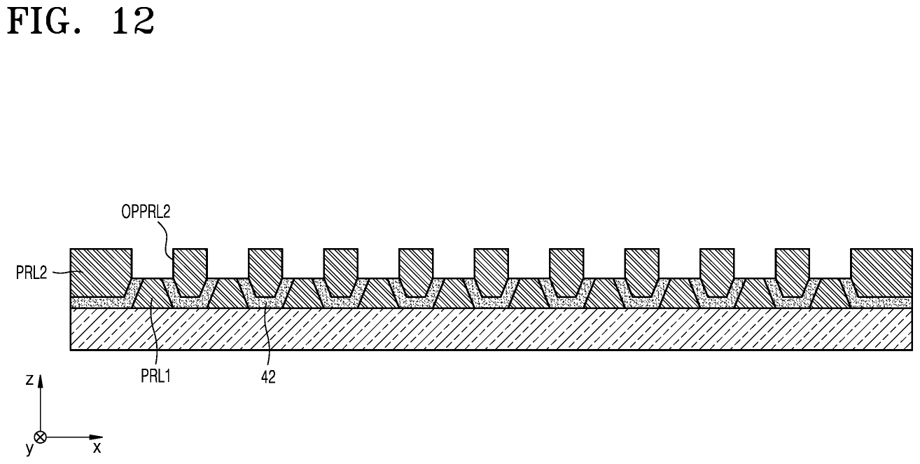

Referring to FIG. 12, the operation of etching a portion of the second mask layer 42 that overlaps the second photo opening OPPRL2 may be seen. That is, a portion of the second mask layer 42 that does not overlap the second photoresist layer PRL2 may be etched. The first photoresist layer PRL1 may be exposed from the second mask layer 42 by etching the second mask layer 42. In an embodiment, the second mask layer 42 may be etched by dry etching using an etching gas, for example. However, this is an illustrative embodiment, and a manner in which the second mask layer 42 is etched is not limited thereto.

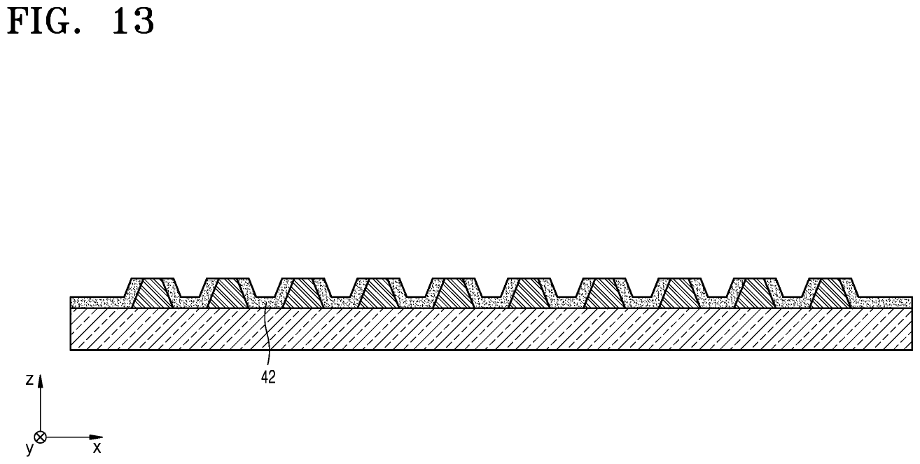

Referring to FIG. 13, the operation of removing the second photoresist layer PRL2 (refer to FIG. 12) may be seen. The second mask layer 42 may be exposed by removing the second photoresist layer PRL2 (refer to FIG. 12).

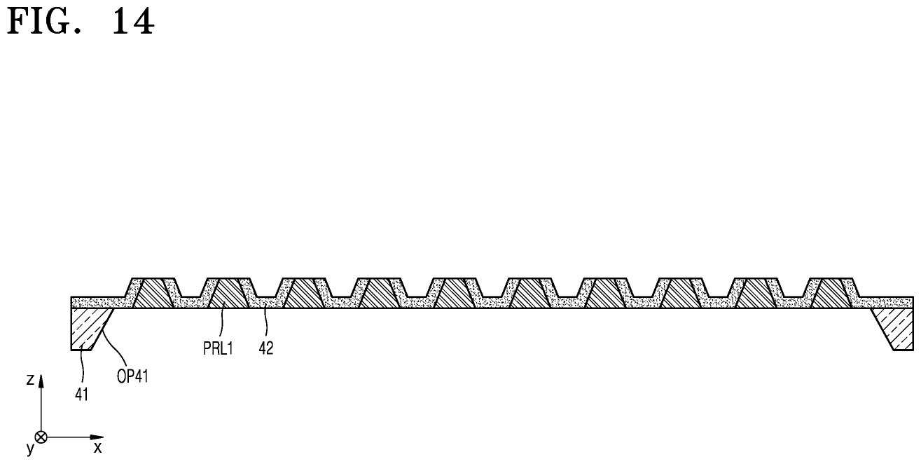

Referring to FIG. 14, the operation of etching the first mask layer 41 may be seen. The first mask opening OP41 may be defined by etching the first mask layer 41. Through the first mask opening OP41, the first photoresist layer PRL1 and the second mask layer 42 may be exposed from the first mask layer 41. The first mask layer 41 may be etched through the photolithography process described above. The first mask layer 41 may be etched by dry etching using an etching gas.

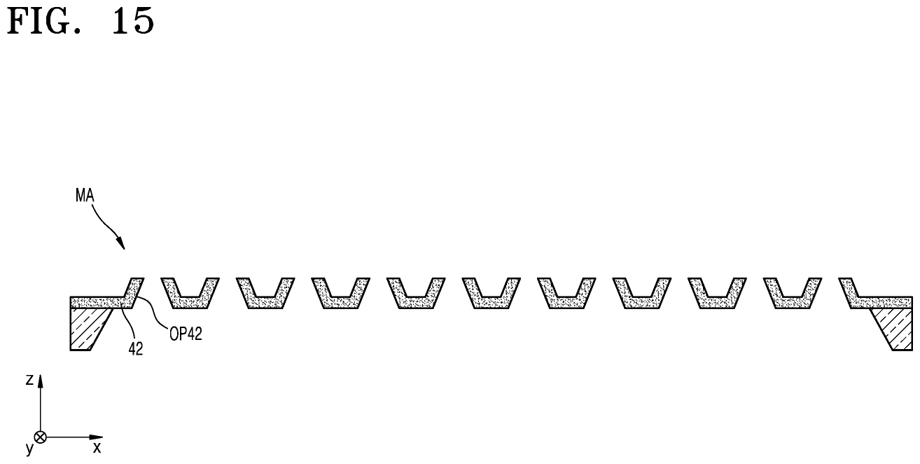

Referring to FIG. 15, the operation of removing the first photoresist layer PRL1 (refer to FIG. 14) may be seen. By removing the first photoresist layer PRL1 (refer to FIG. 14), the second mask opening OP42 may be defined in the second mask layer 42.

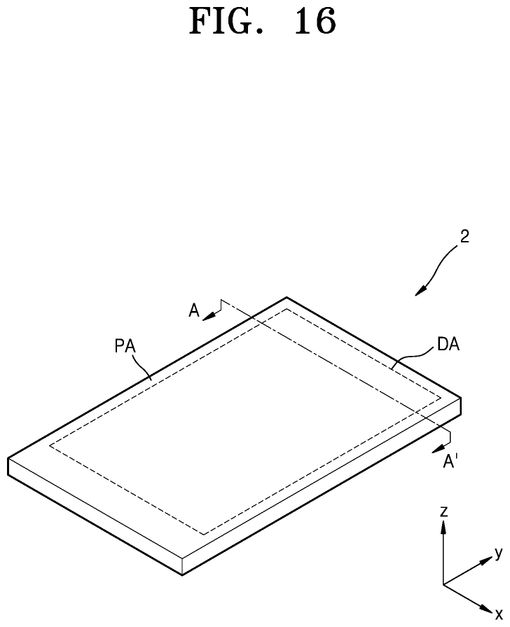

FIG. 16 is a schematic perspective view of an embodiment of a display device 2.

Referring to FIG. 16, the display device 2 includes a display area DA and a peripheral area PA surrounding the display area DA. The display device 2 may provide a predetermined image by light emitted from a plurality of pixels arranged in the display area DA.

The peripheral area PA may surround an entirety of the display area DA. The peripheral area PA is a non-display area where pixels are not arranged, and a driver or wires providing an electrical signal or power to the pixels may be disposed in the peripheral area PA.

As shown in FIG. 16, the display device 2 may have a quadrangular shape, e.g., rectangular shape in which a horizontal length is greater than a vertical length, but the disclosure is not limited thereto. The display device 2 may have various shapes, such as a polygonal shape, a circular shape, or an oval shape.

Although an organic light-emitting display device is described below in an embodiment of the display device 2 in an embodiment, a display device described herein is not limited thereto. In another embodiment, other types of display devices, such as a quantum dot light-emitting display, may be used.

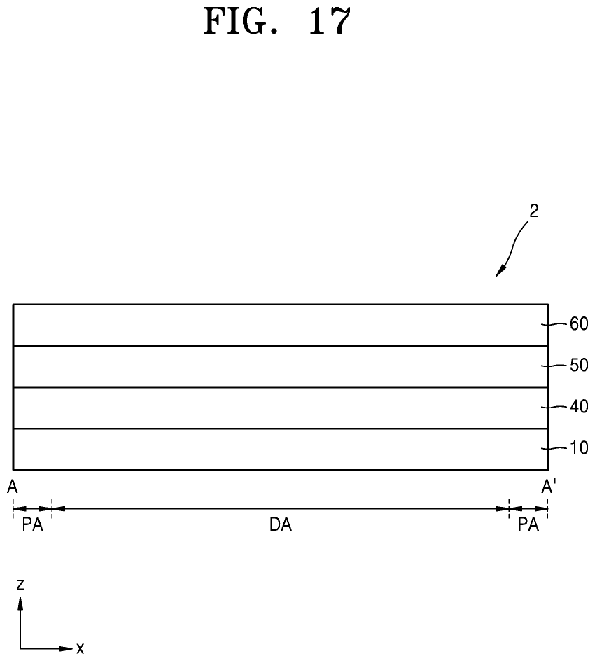

FIG. 17 is a schematic cross-sectional view of an embodiment of the display device 2. FIG. 17 may correspond to a line A-A′ of FIG. 16.

Referring to FIG. 17, the display device 2 may include a display panel 10, an input sensing layer 40 disposed on the display panel 10, and an optical functional layer 50, and these elements may be covered by a window 60. The display device 2 may be any of various electronic devices, such as a mobile phone, a notebook computer, and a smartwatch.

The display panel 10 may display an image. The display panel 10 includes pixels arranged in the display area DA. The pixels may include a display element and a pixel circuit connected thereto. The display element may include an organic light-emitting diode or a quantum-dot organic light-emitting diode.

The input sensing layer 40 obtains coordinate information according to an external input, e.g., a touch event. The input sensing layer 40 may include a sensing electrode (or touch electrode), and trace lines connected to the sensing electrode. The input sensing layer 40 may be disposed on the display panel 10. The input sensing layer 40 may sense an external input by a mutual-capacitance (e.g., a mutual-cap) method and/or a self-capacitance (e.g., a self-cap) method.

The input sensing layer 40 may be formed directly on the display panel 10, or may be separately formed and then bonded to the display panel 10 through an adhesive layer, such as an optical clear adhesive. In an embodiment, the input sensing layer 40 may be continuously formed after a process of forming the display panel 10, for example. In this case, the input sensing layer 40 may be understood as a part of the display panel 10, and the adhesive layer may not be between the input sensing layer 40 and the display panel 10. FIG. 17 shows the input sensing layer 40 between the display panel 10 and the optical functional layer 50. However, in another embodiment, the input sensing layer 40 may be disposed on the optical functional layer 50.

The optical functional layer 50 may include an anti-reflection layer. The anti-reflection layer may reduce the reflectance of light (e.g., external light) incident from the outside toward the display panel 10 through the window 60. In an embodiment, the anti-reflection layer may include a black matrix and color filters. The color filters may be arranged by taking into account a color of light emitted from each of the pixels of the display panel 10.

In another embodiment, the anti-reflection layer may include a phase retarder and a polarizer. The phase retarder may be of a film type or a liquid crystal coating type and may include a λ/2 phase retarder and/or a λ/4 phase retarder. The polarizer may also be of a film type or a liquid crystal coating type. The film type may include an elongated synthetic resin film, and the liquid crystal coating type may include liquid crystals arranged in a predetermined arrangement. The phase retarder and the polarizer may further include a protection film. The phase retarder and the polarizer themselves or the protection film may be defined as a base layer of the anti-reflection layer.

In another embodiment, the anti-reflection layer may include a destructive interference structure. The destructive interference structure may include a first reflection layer and a second reflection layer respectively arranged in different layers. First reflected light and second reflected light respectively reflected by the first reflection layer and the second reflection layer may destructively interfere with each other, and thus, the reflectance of external light may be reduced.

In an embodiment, the optical functional layer 50 may be continuously formed after a process of forming the display panel 10 and/or the input sensing layer 40. In this case, an adhesive layer may not be between the optical functional layer 50 and the display panel 10 and/or the input sensing layer 40.

Although not shown in FIG. 17, a layer including an optical clear adhesive or an optical clear resin may be between the window 60 and the optical functional layer 50.

FIG. 18 is a schematic plan view of an embodiment of the display panel 10. As described in FIG. 17, a display device in an embodiment may include the display panel 10. FIG. 18 may be understood as showing the way that the substrate 100 of the display panel 10 looks.

Referring to FIG. 18, the display panel 10 includes the display area DA and the peripheral area PA outside the display area DA. The display area DA is a portion that displays an image, and a plurality of pixels P may be arranged in the display area DA. The display area DA may have various shapes, e.g., a circular shape, an oval shape, a polygonal shape, or a shape of a certain figure. FIG. 18 shows the display area DA having a substantially quadrangular shape, e.g., rectangular shape with round corners.

Each of the pixels P refers to a sub-pixel, and may include a display element, such as an organic light-emitting diode. The pixel P may emit red, green, blue, or white light, for example.

The peripheral area PA may be disposed outside the display area DA. Outer circuits driving the pixel P may be arranged in the peripheral area PA. A first scan driving circuit 11, a second scan driving circuit 12, an emission control driving circuit 13, a terminal 14, a driving power supply wire 15, and a common power supply wire 16 may be arranged in the peripheral area PA.

The first scan driving circuit 11 may provide a scan signal to the pixel P through a scan line SL. The second scan driving circuit 12 may be disposed parallel to the first scan driving circuit 11 with the display area DA therebetween. Some of the pixels P arranged in the display area DA may be electrically connected to the first scan driving circuit 11, and the others may be connected to the second scan driving circuit 12. In some cases, the second scan driving circuit 12 may be omitted, and all of the pixels P arranged in the display area DA may be electrically connected to the first scan driving circuit 11.

The emission control driving circuit 13 may be disposed at the side of the first scan driving circuit 11 and may provide an emission control signal to the pixel P through an emission control line EL. Although FIG. 16 shows the emission control driving circuit 13 disposed only at one side of the display area DA, the emission control driving circuit 13 may be disposed at opposite sides of the display area DA like the first and second scan driving circuits 11 and 12.

In an embodiment, the peripheral area PA may include a bending area extending to one side of the display area DA (in a direction −y). The bending area may be bent to the rear of the display area DA, and thus, the area of a non-display area visible when viewed from the front of the display device may be reduced.

A driving chip 20 may be disposed in the peripheral area PA. The driving chip 20 may include an integrated circuit driving the display panel 10. The integrated circuit may be a data driving integrated circuit generating a data signal, but the disclosure is not limited thereto.

The terminal 14 may be disposed in the peripheral area PA. The terminal 14 may not be covered by an insulating layer but may be exposed and electrically connected to a printed circuit board 30. A terminal 34 of the printed circuit board 30 may be electrically connected to the terminal 14 of the display panel 10.

The printed circuit board 30 transfer a signal or power of a controller (not shown) to the display panel 10. A control signal generated by the controller may be transferred to each of the driving circuits through the printed circuit board 30. In addition, the controller may transfer a driving voltage ELVDD to the driving power supply wire 15 and may provide a common voltage ELVSS to the common power supply wire 16. The driving voltage ELVDD may be transferred to each pixel P through a driving voltage line PL connected to the driving power supply wire 15, and the common voltage ELVSS may be transferred to an opposite electrode of the pixel P connected to the common power supply wire 16. The driving power supply wire 15 may extend in one direction (e.g., an x-axis direction) below the display area DA. The common power supply wire 16 may have a loop shape with one side open and thus may partially surround the display area DA.

The controller may generate a data signal, and the generated data signal may be transferred to an input line IL through the driving chip 20 and may be transferred to the pixel P through a data line DL connected to the input line IL. For reference, the term “line” may denote a “wire.” This also applies to the following embodiments and modifications thereof.

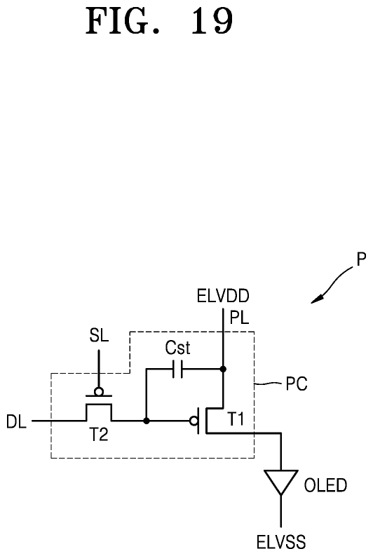

FIG. 19 is an equivalent circuit diagram of an embodiment of the pixel P included in a display device.

Referring to FIG. 19, the pixel PX may include a pixel circuit PC and an organic light-emitting diode OLED as a display element connected to the pixel circuit PC. The pixel circuit PC may include a first thin-film transistor T1, a second thin-film transistor T2, and a storage capacitor Cst. Each pixel P may emit red, green, or blue light, or red, green, blue, or white light, through the organic light-emitting diode OLED, for example.

The second thin-film transistor T2, which is a switching thin-film transistor, may be connected to the scan line SL and the data line DL, and may transfer a data voltage input from the data line DL to the first thin-film transistor T1, based on a switching voltage input from the scan line SL. The storage capacitor Cst may be connected to the second thin-film transistor T2 and the driving voltage line PL and may store a voltage corresponding to a difference between a voltage received from the second thin-film transistor T2 and the driving voltage ELVDD supplied to the driving voltage line PL.

The first thin-film transistor T1, which is a driving thin-film transistor, may be connected to the driving voltage line PL and the storage capacitor Cst, and may control a driving current flowing through the organic light-emitting diode OLED from the driving voltage line PL, in response to a voltage value stored in the storage capacitor Cst. The organic light-emitting diode OLED may emit light having predetermined brightness according to the driving current. An opposite electrode (e.g., a cathode) of the organic light-emitting diode OLED may receive the common voltage ELVSS. However, the disclosure is not limited thereto, and the opposite electrode (e.g., a cathode) of the organic light-emitting diode OLED may receive a ground voltage.

Although FIG. 19 shows the pixel circuit PC including two thin-film transistors and one storage capacitor, the disclosure is not limited thereto. The number of thin-film transistors and the number of storage capacitors may be variously modified according to the design of the pixel circuit PC. In an embodiment, the pixel circuit PC may further include four or five or more thin-film transistors in addition to the two thin-film transistors described above, for example.

FIG. 20 is a schematic cross-sectional view taken along line D-D′ of an embodiment of the display device 2 shown in FIG. 18.

Referring to FIG. 20, the display panel 10 may include the substrate 100.

The substrate 100 may include a glass material or polymer resin. In an embodiment, the substrate 100 may have a multi-layer structure in which a base layer including polymer resin and a barrier layer for preventing the penetration of external foreign materials are alternately stacked.

The base layer may include polymer resin, such as polyethersulfone (“PES”), polyarylate (“PAR”), polyetherimide (“PEI”), polyethylene naphthalate (“PEN”), polyethylene terephthalate (“PET”), polyphenylene sulfide (“PPS”), polyimide (“PI”), polycarbonate (“PC”), cellulose triacetate (“TAC”), cellulose acetate propionate (“CAP”), etc.

The barrier layer may include an inorganic material, such as silicon nitride (SiNx) and/or silicon oxide (SiOx).

A first pixel P1 emitting light of a first color, a second pixel P2 emitting light of a second color, and a third pixel P3 emitting light of a third color may be arranged in the display area DA of the substrate 100. Each of the first color, the second color, and the third color may be one of red, blue, green, or white.

The first pixel P1 may include a first pixel circuit PC1 and a first organic light-emitting diode OLED1 as a display element electrically connected to the first pixel circuit PC1. The second pixel P2 may include a second pixel circuit PC2 and a second organic light-emitting diode OLED2 electrically connected to the second pixel circuit PC2. The third pixel P3 may include a third pixel circuit PC3 and a third organic light-emitting diode OLED3 electrically connected to the third pixel circuit PC3.

A buffer layer 201 for preventing impurities from penetrating into a semiconductor layer Act of a thin-film transistor TFT of the first pixel circuit PC1 may be on the substrate 100. The buffer layer 201 may include an inorganic insulating material, such as silicon nitride (SiNx), silicon oxynitride (SiON), and silicon oxide (SiOx), and may have a single-layer or multi-layer structure including one or more of the inorganic insulating materials described above.

The first pixel circuit PC1, the second pixel circuit PC2, and the third pixel circuit PC3 may be disposed on the buffer layer 201. The first pixel circuit PC1 includes the thin-film transistor TFT and the storage capacitor Cst. The thin-film transistor TFT may include the semiconductor layer Act, a gate electrode GE, a source electrode SE, and a drain electrode DE. The thin-film transistor TFT shown in FIG. 20 may correspond to the first thin-film transistor described with reference to FIG. 19. The data line DL is electrically connected to a second thin-film transistor which is not shown in FIG. 20 but is included in the first pixel circuit PC1. In the illustrated embodiment, a top gate type is shown in which the gate electrode GE is disposed above the semiconductor layer Act with a gate insulating layer 203 therebetween. However, in another embodiment, the thin-film transistor TFT may be of a bottom gate type. The second pixel circuit PC2 and the third pixel circuit PC3 may have the same or similar structure as the first pixel circuit PC1. Each element of the first pixel circuit PC1 is mainly described below.

The semiconductor layer Act may include polysilicon. In an alternative embodiment, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), titanium (Ti), etc., and may have a multi-layer or single-layer structure including one or more of the materials described above.

The gate insulating layer 203 between the semiconductor layer Act and the gate electrode GE may include an inorganic insulating material, such as silicon oxide (SiOx), silicon nitride (SiNx), silicon oxynitride (SiON), aluminum oxide (Al2O3), titanium oxide (TiOx), tantalum oxide (Ta2O5), and hafnium oxide (HfO2). The gate insulating layer 203 may have a single-layer or multi-layer structure including one or more of the above-described materials.

The storage capacitor Cst may include a bottom electrode CE1 and a top electrode CE2 overlapping each other with a first inter-insulating layer 205 therebetween. The storage capacitor Cst may overlap the thin-film transistor TFT. In this regard, FIG. 20 shows that the gate electrode GE of the thin-film transistor TFT is the bottom electrode CE1 of the storage capacitor Cst. In another embodiment, the storage capacitor Cst may not overlap the thin-film transistor TFT. The storage capacitor Cst may be covered by a second inter-insulating layer 207. The top electrode CE2 of the storage capacitor Cst may include a conductive material including molybdenum (Mo), aluminum (Al), copper (Cu), titanium (Ti), etc., and may have a multi-layer or single-layer structure including one or more of the materials described above.

The first inter-insulating layer 205 and the second inter-insulating layer 207 may include an inorganic insulating material, such as silicon oxide (SiOx), silicon nitride (SiNx), silicon oxynitride (SiON), aluminum oxide (Al2O3), titanium oxide (TiOx), tantalum oxide (Ta2O5), and hafnium oxide (HfO2). The first inter-insulating layer 205 and the second inter-insulating layer 207 may have a single-layer or multi-layer structure including one or more of the above-described materials.

The source electrode SE and the drain electrode DE may be in the same layer as the data line DL and may include the same material as that of the data line DL. In an embodiment, the source electrode SE, the drain electrode DE, and the data line DL may be on the second inter-insulating layer 207, for example. The source electrode SE, the drain electrode DE, and the data line DL may include a highly conductive material. The source electrode SE and the drain electrode DE may include a conductive material including molybdenum (Mo), aluminum (Al), copper (Cu), titanium (Ti), etc., and may have a multi-layer or single-layer structure including one or more of the materials described above. In an embodiment, the source electrode SE, the drain electrode DE, and the data line DL may each have a multi-layer structure including a titanium layer, an aluminum layer, and a titanium layer (Ti/Al/Ti).

The first pixel circuit PC1, the second pixel circuit PC2, and the third pixel circuit PC3 each including the thin-film transistor TFT and the storage capacitor Cst may be covered by a first organic insulating layer 209. The first organic insulating layer 209 may have a substantially flat top surface.

The first organic light-emitting diode OLED1 electrically connected to the first pixel circuit PC1, the second organic light-emitting diode OLED2 electrically connected to the second pixel circuit PC2, and the third organic light-emitting diode OLED3 electrically connected to the third pixel circuit PC3 may be above the first organic insulating layer 209.

The first pixel circuit PC1 may be electrically connected to a first pixel electrode 221r of the first organic light-emitting diode OLED1. In an embodiment, as shown in FIG. 20, a contact metal layer CM may be between the thin-film transistor TFT and the first pixel electrode 221r, for example. The contact metal layer CM may be connected to the thin-film transistor TFT through a contact hole penetrating the first organic insulating layer 209, and the first pixel electrode 221r may be connected to the contact metal layer CM through a contact hole penetrating a second organic insulating layer 211 disposed on the contact metal layer CM. The contact metal layer CM may include a conductive material including molybdenum (Mo), aluminum (Al), copper (Cu), titanium (Ti), etc., and may have a multi-layer or single-layer structure including one or more of the materials described above. In an embodiment, the contact metal layer CM may have a multi-layer structure including Ti/Al/Ti.

The first organic insulating layer 209 and the second organic insulating layer 211 may include an organic insulating material, such as a general commercial polymer, such as polymethylmethacrylate (“PMMA”) or polystyrene (“PS”), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and any combinations thereof. In an embodiment, the first organic insulating layer 209 and the second organic insulating layer 211 may include polyimide.

In another embodiment, one of the first organic insulating layer 209 and the second organic insulating layer 211 may be omitted. In this case, the contact metal layer CM may be omitted.

The first organic light-emitting diode OLED1 may include the first pixel electrode 221r, a first emission layer 222r, and a first opposite electrode 223r. The second organic light-emitting diode OLED2 may include a second pixel electrode 221g, a second emission layer 222g, and a second opposite electrode 223g. The third organic light-emitting diode OLED3 may include a third pixel electrode 221b, a third emission layer 222b, and a third opposite electrode 223b. The second organic light-emitting diode OLED2 and the third organic light-emitting diode OLED3 may each have a structure that is similar to or the same as that of the first organic light-emitting diode OLED1.

The first pixel electrode 221r may be on the second organic insulating layer 211. The first pixel electrode 221r may include conductive oxide, such as indium tin oxide (“ITO”), indium zinc oxide (“IZO”), zinc oxide (ZnO), indium oxide (In2O3), indium gallium oxide (“IGO”), or aluminum zinc oxide (“AZO”). In another embodiment, the first pixel electrode 221r may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In another embodiment, the first pixel electrode 221r may further include a layer including ITO, IZO, ZnO, or In2O3 on/under the above-described reflective layer.

A pixel-defining layer 213 and a bank layer 215 may be on the first pixel electrode 221r. The pixel-defining layer 213 may overlap edges of the first pixel electrode 221r when viewed in a direction that is substantially perpendicular to the substrate 100 (a z-axis direction). The pixel-defining layer 213 may include an inorganic insulating material, such as silicon nitride (SiNx), silicon oxynitride (SiON), or silicon oxide (SiOx).

A first residual sacrificial layer 212R may be between the first pixel electrode 221r and the pixel-defining layer 213. The first residual sacrificial layer 212R may be a portion remaining after a sacrificial layer protecting a top surface of the first pixel electrode 221r is removed. The first residual sacrificial layer 212R may be in an area where the pixel-defining layer 213 and the first pixel electrode 221r overlap each other when viewed in the direction that is substantially perpendicular to the substrate 100 (the z-axis direction). In an embodiment, the first residual sacrificial layer 212R may be disposed along the edges of the first pixel electrode 221r to expose a central portion of the first pixel electrode 221r, for example.

The first residual sacrificial layer 212R may be continuously formed with the first pixel electrode 221r and may include a material that may be selectively etched without damaging the first pixel electrode 221r. In an embodiment, the first residual sacrificial layer 212R may include indium gallium zinc oxide (“IGZO”) and/or indium zinc oxide (“IZO”), for example.

The first residual sacrificial layer 212R and the pixel-defining layer 213 may overlap the edges of the first pixel electrode 221r and increase a distance between the first pixel electrode 221r and the bank layer 215 and the first opposite electrode 223r and thus may prevent an arc or the like from occurring therebetween. In some embodiments, the sacrificial layer may be completely removed, and thus, the first residual sacrificial layer 212R may not be present. In this case, a groove defined by removing the sacrificial layer between the first pixel electrode 221r and the pixel-defining layer 213 may be empty or buried by the first emission layer 222r described below.

The bank layer 215 may be on the pixel-defining layer 213. The bank layer 215 may include a conductive material. In an embodiment, the bank layer 215 may include a conductive material including molybdenum (Mo), aluminum (Al), copper (Cu), titanium (Ti), etc., and may have a multi-layer or single-layer structure including one or more of the materials described above, for example. In an embodiment, the bank layer 215 may have a two-layer structure including Al/Ti or a three-layer structure including Ti/Al/Ti, for example.

The pixel-defining layer 213 and the bank layer 215 may extend from the display area DA of the substrate 100 to the peripheral area PA (refer to FIG. 18), and the bank layer 215 may be in direct contact with the common power supply wire 16 (refer to FIG. 18) disposed in the peripheral area PA (refer to FIG. 18) through an opening area in the pixel-defining layer 213. Accordingly, the bank layer 215 may serve as a connection electrode or an auxiliary wire for transferring the common voltage ELVSS to the first opposite electrode 223r, the second opposite electrode 223g, and the third opposite electrode 223b described below.

A first conductive layer 217 may be on the bank layer 215. The first conductive layer 217 may have a tip 217T protruding outward with respect to a center of the first pixel electrode 221r. When viewed in a direction that is perpendicular to a top surface of the substrate 100 (the z-axis direction), the tip 217T of the first conductive layer 217 may have a loop shape completely surrounding the first pixel electrode 221r.

A first opening OP1 may penetrate through the pixel-defining layer 213, the bank layer 215, and the first conductive layer 217 and expose a central portion of the top surface of the first pixel electrode 221r, and the first emission layer 222r described below may overlap and contact the first pixel electrode 221r through the first opening OP1. Accordingly, the first opening OP1 may define a first emission area EA1. An area outside the first emission area EA1 may be defined as a non-emission area NEA. Likewise, a second opening OP2 may define a second emission area EA2, and a third opening OP3 may define a third emission area EA3.

A portion of the first conductive layer 217 may be spaced apart from the bank layer 215 in a direction that is perpendicular to the substrate 100 (the z-axis direction) and may constitute the tip 217T protruding outward with respect to the center of the first pixel electrode 221r. Because the tip 217T of the first conductive layer 217 is formed by removing a portion of a sacrificial layer between the first conductive layer 217 and the bank layer 215, the first conductive layer 217 may have an undercut structure. Accordingly, the tip 217T of the first conductive layer 217 may constitute an eaves structure in which a bottom surface is exposed. A protrusion length (d1) of the tip 217T of the first conductive layer 217 may be about 0.5 micrometer (μm) or greater. In some embodiments, the protrusion length (d1) of the tip 217T of the first conductive layer 217 may be about 0.3 μm to about 1 μm or about 0.3 μm to about 0.7 μm.

The first conductive layer 217 may include a conductive material. In an embodiment, the first conductive layer 217 may include a conductive material including molybdenum (Mo), aluminum (Al), copper (Cu), titanium (Ti), etc., and may have a multi-layer or single-layer structure including one or more of the materials described above, for example. In an embodiment, the first conductive layer 217 may have a two-layer structure including Al/Ti or a three-layer structure including Ti/Al/Ti, for example.

In an embodiment, a low reflection layer (not shown) may be on the first conductive layer 217. The low reflection layer may be a layer having a surface reflectance that is less than that of the first conductive layer 217. The low reflection layer may prevent light (e.g., external light) incident toward the display device 2 from being reflected on a surface of the first conductive layer 217 and visible to a user of the display device 2.

In an embodiment, the low reflection layer may include a low reflection material. The low reflection material may include metal oxide having a relatively high extinction rate, that is, a relatively high extinction coefficient (k). In an embodiment, the low reflection layer may include at least one of copper oxide (CuO), calcium oxide (CaO), molybdenum oxide (MoOx), and zinc oxide (ZnO), for example. In some embodiments, the low reflection layer may include a combination of copper oxide (CuO) and calcium oxide (CaO), for example.

A second residual sacrificial layer 214R may be between the first conductive layer 217 and the bank layer 215. The second residual sacrificial layer 214R may be a residual portion of a sacrificial layer removed to form the tip 217T of the first conductive layer 217. The second residual sacrificial layer 214R may be spaced apart from the first pixel electrode 221r by a predetermined distance when viewed in the direction that is substantially perpendicular to the substrate 100 (the z-axis direction) and may have a loop shape completely surrounding the first pixel electrode 221r. The first conductive layer 217 may have an undercut structure due to the second residual sacrificial layer 214R.

The second residual sacrificial layer 214R may determine the protrusion length d1 of the tip 217T of the first conductive layer 217. In an embodiment, the second residual sacrificial layer 214R may be at an inner side of an end of the tip 217T of the first conductive layer 217, and the protrusion length d1 of the tip 217T may be a length from a side wall of the second residual sacrificial layer 214R to the end of the tip 217T, for example.

The second residual sacrificial layer 214R may include a material that may be selectively etched without damaging the first pixel electrode 221r, the bank layer 215, and the first conductive layer 217. In an embodiment, the second residual sacrificial layer 214R may include the same material as that of the first residual sacrificial layer 212R, for example. The second residual sacrificial layer 214R may include IGZO and/or IZO.

The first emission layer 222r may be disposed over the first pixel electrode 221r and the first conductive layer 217. In an embodiment, the first emission layer 222r may contact the first pixel electrode 221r through the first opening OP1, for example. The first emission layer 222r may include a polymer organic material or low-molecular weight organic material emitting light of the first color (e.g., red). In another embodiment, the first emission layer 222r may include an inorganic material or quantum dots.

The first emission layer 222r may include a first functional layer (not shown) and a second functional layer (not shown) at the top and/or the bottom. The first functional layer may include a hole transport layer (“HTL”) and/or a hole injection layer (“HIL”). The second functional layer may include an electron transport layer (“ETL”) and/or an electron injection layer (“EIL”).

FIG. 20 shows a single stack structure including a single emission layer. However, in some embodiments, the display device 2 may have a tandem structure, which is a multi-stack structure including a plurality of emission layers. In the tandem structure, a charge generation layer (“CGL”) may be disposed between a plurality of stacks.

The first emission layer 222r may be disconnected from a dummy portion 222rp by the tip 217T of the first conductive layer 217. In this regard, the first emission layer 222r may include the same material and/or the same number of sub-layers (e.g., the first functional layer, the second functional layer, etc.) as the dummy portion 222rp.

At least one first hole 222rh exposing a portion of a top surface of the first conductive layer 217 may be defined in the first emission layer 222r.

The second emission layer 222g may include a polymer organic material or low-molecular weight organic material emitting light of the second color (e.g., green), and the third emission layer 222b may include a polymer organic material or low-molecular weight organic material emitting light of the third color (e.g., blue).

The first opposite electrode 223r may be disconnected from a dummy portion 223rp by tips 217T of the first conductive layer 217. The first opposite electrode 223r may include the same material as that of the dummy portion 223rp. In an embodiment, a dummy portion 223bp may be similar to the dummy portion 223rp, and therefore a detailed description thereof may be omitted.

The first opposite electrode 223r may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloys thereof. In an alternative embodiment, the first opposite electrode 223r may further include a layer, such as ITO, IZO, ZnO, or In2O3, on a (semi)transparent layer including the above-described material.

A first inorganic encapsulation layer 311 may be on the first opposite electrode 223r. The first inorganic encapsulation layer 311 has relatively good step coverage and thus may cover at least a portion of the exposed bottom surface of the tip 217T of the first conductive layer 217. In an embodiment, the first inorganic encapsulation layer 311 may be continuously formed to cover top and side surfaces of the first opposite electrode 223r, side surfaces of the first emission layer 222r, side and bottom surfaces of the tip 217T of the first conductive layer 217, side surfaces of the second residual sacrificial layer 214R, and a top surface of the bank layer 215, for example.

The first inorganic encapsulation layer 311 may include an inorganic insulating material, such as silicon nitride (SiNx), silicon oxynitride (SiON), and silicon oxide (SiOx). The first inorganic encapsulation layer 311 may be in direct contact with a metal surface at the side and bottom surfaces of the tip 217T of the first conductive layer 217, thereby forming an inorganic contact region ICR. Accordingly, the inorganic contact region ICR may form a closed loop completely surrounding the first organic light-emitting diode OLED1 to reduce or block a path through which impurities, such as moisture and/or air, penetrate.

As shown in FIG. 20, a second inorganic encapsulation layer 312 may encapsulate the second organic light-emitting diode OLED2, and the third inorganic encapsulation layer 313 may encapsulate the third organic light-emitting diode OLED3. The first inorganic encapsulation layer 311, the second inorganic encapsulation layer 312, and the third inorganic encapsulation layer 313 may allow formation of the inorganic contact region ICR in the display area DA, and thus, an inorganic contact region of the peripheral area PA (refer to FIG. 18) that is desired to reduce a delamination defect due to an emission layer may be reduced. In addition, an organic light-emitting diode may be encapsulated for each pixel, and thus, even when a path through which impurities, such as moisture and/or air, penetrate occurs at one pixel or a boundary of the substrate 100, the resulting defect may be prevented from spreading to neighboring pixels.

An organic planarization layer 410 may cover the first inorganic encapsulation layer 311, the second inorganic encapsulation layer 312, and the third inorganic encapsulation layer 313. The organic planarization layer 410 may cover unevenness caused by the pixel-defining layer 213, the bank layer 215, and the first bank layer 217 and provide a flat base surface to elements disposed on the organic planarization layer 410. The organic planarization layer 410 may include a polymer-based material. In embodiments, the polymer-based material may include acryl-based resin, epoxy-based resin, polyimide, and polyethylene.

In an embodiment, a refractive index of the organic planarization layer 410 may be greater than refractive indices of the first inorganic encapsulation layer 311, the second inorganic encapsulation layer 312, and the third inorganic encapsulation layer 313. In an embodiment, the refractive index of the organic planarization layer 410 may be about 1.6 or greater, for example. The refractive index of the organic planarization layer 410 may be about 1.6 to about 1.9. The organic planarization layer 410 may further include dispersed particles for a relatively high refractive index. In an embodiment, metal oxide particles, such as zinc oxide (ZnOx), titanium oxide (TiO2), zirconium oxide (ZrO2), barium titanate (BaTiO3), etc., may be dispersed in the organic planarization layer 410, for example.

A protection layer 420 may be on the organic planarization layer 410. The protection layer 420 may include an inorganic insulating material, such as silicon nitride (SiNx), silicon oxynitride (SiON), and silicon oxide (SiOx). In an embodiment, a refractive index of the protection layer 420 may be less than that of the organic planarization layer 410.

An anti-reflection layer 500 including a first color filter 510, a second color filter 520, a third color filter 530, a light-blocking layer 540, and an overcoat layer 550 may be on the protection layer 420. The anti-reflection layer 500 may reduce the reflectance of light (e.g., external light) incident from the outside toward the display device 2.

The light-blocking layer 540 may overlap the bank layer 215 and the first conductive layer 217 to at least partially absorb reflected light due to the bank layer 215 and the first conductive layer 217 in the non-emission area NEA. In this regard, the non-emission area NEA may be defined as an area that does not overlap the first emission area EA1, the second emission area EA2, and the third emission area EA3. The light-blocking layer 540 may include a black pigment. The light-blocking layer 540 may be a black matrix. A first filter opening 5400P1 corresponding to the first emission area EA1, a second filter opening 5400P2 corresponding to the second emission area EA2, and a third filter opening 5400P3 corresponding to the third emission area EA3 may be defined in the light-blocking layer 540.

The first color filter 510 may be disposed in the first filter opening 5400P1 to correspond to the first emission layer 222r disposed therebelow. The first color filter 510 may selectively transmit light emitted by the first emission layer 222r. In an embodiment, the first color filter 510 shown in FIG. 20 may be a red color filter that transmits red light, for example.

Likewise, the second color filter 520 may be disposed in the second filter opening 5400P2 to correspond to the second emission layer 222g. The second colorfilter 520 may selectively transmit light emitted by the second emission layer 222g. The third color filter 530 may be disposed in the third filter opening 5400P3 to correspond to the third emission layer 222b. The third color filter 530 may selectively transmit light emitted by the third emission layer 222b. In an embodiment, the second color filter 520 shown in FIG. 20 may be a green color filter that transmits green light, and the third color filter 530 may be a blue color filter that transmits blue light, for example.

The overcoat layer 550 may be disposed over the first to third color filters 510, 520, and 530. The overcoat layer 550, which is a light-transmitting layer, may cover unevenness caused by the first to third color filters 510, 520, and 530 and the light-blocking layer 540 and may provide a flat top surface. The overcoat layer 550 may include a colorless light-transmitting organic material, such as acryl-based resin.

According to one or more of the embodiments described above, in an apparatus for manufacturing a display device, a manufacturing speed may be improved, damage to a display substrate may be reduced, and durability of a mask assembly may be improved.

Effects of the disclosure is not limited thereto, and other unmentioned effects will be apparent to one of ordinary skill in the art from the following claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a chamber;
a mask assembly disposed in the chamber and facing a display substrate, the mask assembly comprising:
a first mask layer in which a first mask opening is defined; and
a second mask layer which is disposed on the first mask layer and in which a second mask opening overlapping the first mask opening is defined, the second mask layer comprising:
a 2-1^{st} mask portion; and
a 2-2^{nd} mask portion protruding from the 2-1^{st} mask portion toward the display substrate;
a magnetic force portion which is disposed in the chamber and applies magnetic force to the mask assembly; and
a deposition source which is disposed in the chamber, faces the mask assembly and supplies a deposition material so that the deposition material passes through the mask assembly and is deposited on the display substrate.

2. The apparatus of claim 1, wherein an upper surface of the 2-2^{nd} mask portion contacts the display substrate.

3. The apparatus of claim 2, wherein the display substrate is exposed from the second mask layer through the second mask opening.

4. The apparatus of claim 1, wherein an upper surface of the 2-1^{st} mask portion is spaced apart from the display substrate.

5. The apparatus of claim 1, wherein a width of the second mask opening gradually decreases in a direction toward the display substrate.

6. The apparatus of claim 1, wherein the second mask opening comprises:
a 2-1^{st} mask opening defined in the 2-1^{st} mask portion; and
a 2-2^{nd} mask opening connected to the 2-1^{st} mask opening and defined in the 2-2^{nd} mask portion.

7. The apparatus of claim 1, wherein the 2-1^{st} mask portion and the 2-2^{nd} mask portion are unitary with each other as a single body.

8. A method of manufacturing a display device, the method comprising:
arranging a display substrate in a chamber;
arranging a mask assembly in the chamber;
applying, by a magnetic force portion, magnetic force to the mask assembly; and
supplying, by a deposition source, a deposition material toward the mask assembly,
wherein the arranging the mask assembly comprises:
arranging a first photoresist layer on a first mask layer;
arranging a second mask layer over the first photoresist layer;
etching the second mask layer;
etching the first mask layer; and
removing the first photoresist layer.

9. The method of claim 8, wherein the arranging the first photoresist layer on the first mask layer comprises:
arranging a first photoresist material on the first mask layer;
arranging a first photomask over the first photoresist material, wherein a first photomask opening is defined in the first photomask;
exposing the first photoresist material through the first photomask opening; and
developing the first photoresist material into the first photoresist layer.

10. The method of claim 9, wherein the arranging the first photoresist layer further comprises baking the first photoresist material.

11. The method of claim 8, wherein a side surface of the first photoresist layer is inclined with respect to an upper surface of the first mask layer.

12. The method of claim 8, wherein a second mask opening is defined in the second mask layer by the removing the first photoresist layer.

13. The method of claim 12, wherein the display substrate is exposed from the second mask layer through the second mask opening.

14. The method of claim 12, wherein a width of the second mask opening gradually decreases in a direction toward the display substrate.

15. The method of claim 8, wherein the second mask layer comprises:
a 2-1^{st} mask portion; and
a 2-2^{nd} mask portion protruding from the 2-1^{st} mask portion toward the display substrate.

16. The method of claim 15, wherein an upper surface of the 2-2^{nd} mask portion contacts the display substrate.

17. The method of claim 15, wherein an upper surface of the 2-1^{st} mask portion is spaced apart from the display substrate.

18. The method of claim 15, wherein the 2-1^{st} mask portion and the 2-2^{nd} mask portion are unitary with each other as a single body.
